(19) United States
(12) Patent Application Publication
(10) Pub. No.: US 2014/0356986 A1
(43) Pub. Date: Dec. 4, 2014

(54) PRECISION CONTROLLED COLLAPSE CHIP CONNECTION MAPPING

(71) Applicant: International Business Machines Corporation, Armonk, NY (US)

(72) Inventors: Nicholas G. CLORE, Essex Junction, VT (US); Alissa R. COTE, Winooski, VT (US); Michael C. JOHNSON, Burlington, VT (US); Andrew NORFLEET, Burlington, VT (US)

(21) Appl. No.: 13/906,797

(22) Filed: May 31, 2013

(51) Int. Cl. H01L 23/00; H01L 21/66; G06F 17/50

(52) U.S. Cl. CPC H01L 24/81; G06F 17/5081; H01L 22/12; G06F 17/5077
USPC 438/15; 716/112

(57) ABSTRACT

Systems and methods are provided for improved join structure connections between substrates. More specifically, a method is provided for manufacturing a semiconductor structure. The method includes obtaining a characteristic of an existing first join structure on a first substrate and a characteristic of an existing second join structure on a second substrate. The method further includes analyzing the characteristics of the existing first join structure and the existing second join structure to determine a match between the existing first join structure and the existing second join structure to avoid contact defects.

### FIELD OF THE INVENTION

The invention relates to semiconductor device fabrication, and more particularly, to systems and methods for improved join structure connections between substrates.

### BACKGROUND

Flip chip, also known as controlled collapse chip connection (C4), is a method for interconnecting semiconductor devices, such as integrated circuit (IC) chips and microelectromechanical systems (MEMS), to external circuitry with join structures, such as solder bumps, that have been deposited onto chip pads. The solder bumps are deposited on the chip pads on the top side of the wafer during the final wafer processing step. In order to mount the chip to external circuitry (e.g., a circuit board or another chip or wafer), the chip is flipped over so that a top side of the chip faces down, and is then aligned so that the pads align with matching pads on the external circuitry. Thereafter, the solder is flowed to complete the interconnect.

Traditionally, C4 bumps (solder bumps), such as high temperature C4 bumps, have been used to bond a chip to a substrate, laminate, circuit board, or another chip. However, challenges related to temperature differentiation, C4 bump volume variation, and structural warpage present during joining between the chip and the substrate, laminate, circuit board, or another chip may lead to defects in the final product. For example, challenges related to temperature differentiation, smaller C4 bump pitches, and warpage of the substrate, laminate, circuit board, or the chips may cause defects such as non-wets (e.g., a solder bump that does not bond to the substrate pad metallization during the solder reflow process), solder bridging (e.g., at least two solder bumps flowing together from excess solder), or micro solder balls (e.g., loose micro solder balls formed from excess solder between the chip and the substrate, laminate, circuit board, or another chip), that affect the yield and/or reliability of the adjoined semiconductor device (e.g., a three dimensional (3D) chip stack, which is a chip in which two or more layers of active electronic components are integrated both vertically and horizontally into a single circuit).

The cost and complexity of fabricating semiconductor devices, such as 3D chip stacks, makes traditional methods of scrapping defective joins, laminates, and/or dies less feasible to overcome the challenges described above. Accordingly, there exists a need in the art to overcome the deficiencies and limitations described hereinabove.

### SUMMARY

In a first aspect of the invention, a method is provided for manufacturing a semiconductor structure. The method includes obtaining a characteristic of an existing first join structure on a first substrate and a characteristic of an existing second join structure on a second substrate. The method further includes analyzing the characteristics of the existing first join structure and the existing second join structure to determine a match between the existing first join structure and the existing second join structure to avoid contact defects. At least the step of analyzing the characteristics is performed using a processor.

In a second aspect of the invention, a method is provided for manufacturing a semiconductor structure. The method includes obtaining scan data of existing pre-solder on a laminate or chip and scan data of existing solder on a chip. The method further includes analyzing the scan data of the existing pre-solder and the existing solder to determine whether a match exists between the existing pre-solder and the existing solder to avoid contact defects between the laminate or chip and the chip when attached. The method further includes that when the existing pre-solder does not match the existing solder, performing one of: selecting another substrate to match a solder or pre-solder configuration of the another substrate with a pre-solder configuration of the existing pre-solder on the laminate or chip or a solder configuration of the existing solder on the chip, customizing the existing pre-solder on the laminate or chip, and customizing the existing solder on the chip. At least the step of the analyzing the scan data is performed using a processor.

In a third aspect of the invention, a computer program product is provided comprising a computer readable storage medium having readable program code embodied in the storage medium. The computer program product includes at least one component operable to obtain a characteristic of an existing first join structure on a first substrate and a characteristic of an existing second join structure on a second substrate, and analyze the characteristics of the existing first join structure and the existing second join structure to determine a match between the existing first join structure and the existing second join structure to avoid contact defects.

### BRIEF DESCRIPTION OF THE SEVERAL VIEWS OF THE DRAWINGS

The present invention is described in the detailed description, which follows, in reference to the noted plurality of drawings by way of non-limiting examples of exemplary embodiments of the present invention.

FIG. 1 is an illustrative external environment for implementing the invention in accordance with aspects of the invention;

FIG. 2 is an illustrative process flow of implementing the system in accordance with aspects of the invention;

FIGS. 3A, 3B, 4A, 4B, 5, and 6 are illustrative chip stack structures in accordance with aspects of the invention;

FIG. 7 is an illustrative process flow of implementing the system in accordance with aspects of the invention;

FIGS. 8A and 8B are illustrative chip stack structures in accordance with aspects of the invention;

FIG. 9 is an illustrative process flow of implementing the system in accordance with aspects of the invention;

FIGS. 10A and 10B are illustrative chip stack structures in accordance with aspects of the invention; and

FIG. 11 is a flow diagram of a design process used in semiconductor design, manufacture, and/or test.

### DETAILED DESCRIPTION

The invention relates to semiconductor device fabrication, and more particularly, to systems and methods for improved join structure connections between substrates. More specifically, the present invention provides systems and methods of manufacturing semiconductor devices comprising join structure (e.g., solder bump) connections that substantially minimize or prevent chip join reliability issues or connectability issues between substrates (e.g., adjoining chip, laminate, or circuit board). For example, aspects of the present invention utilize existing scan data from the semiconductor device fabrication to record the volume of individual C4 bumps and laminate or chip pre-solder (e.g., pads) prior to reflow soldering, in order to customize the volume of the individual C4 bumps and laminate or chip pre-solder to dynamically match the size of the individual C4 bumps and laminate or chip pre-solder to the adjoining chip, laminate, or circuit board. Advantageously, these approaches substantially improve the prevention of contact defects (e.g., non-wets, soldering bridging, and the formation of micro solder balls) and provide optimal contact. More advantageously, the dynamic matching of the size of the individual C4 bumps to the laminate or chip pre-solder for the adjoining chip, laminate, or circuit board may be utilized to compensate for chip and/or laminate warpage, and improve the structural integrity of the semiconductor device.

As will be appreciated by one skilled in the art, the following description of embodiments and aspects of the present invention pertain to systems and methods for improved join structure connections between substrates that include the use of C4 bumps and pre-solder as the join structures (e.g., first and second join structures). However, it should be understood by one skilled in the art that the join structures of the present invention may encompass a variety of structures implemented in the fabrication of semiconductor devices for joining substrates together, such as micro bumps and micro pillars, without departing from the scope and spirit of the described embodiments.

As will also be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable storage medium that can direct a computer, other programmable data processing apparatus, or other devices to function in a particular manner, such that the instructions stored in the computer readable storage medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

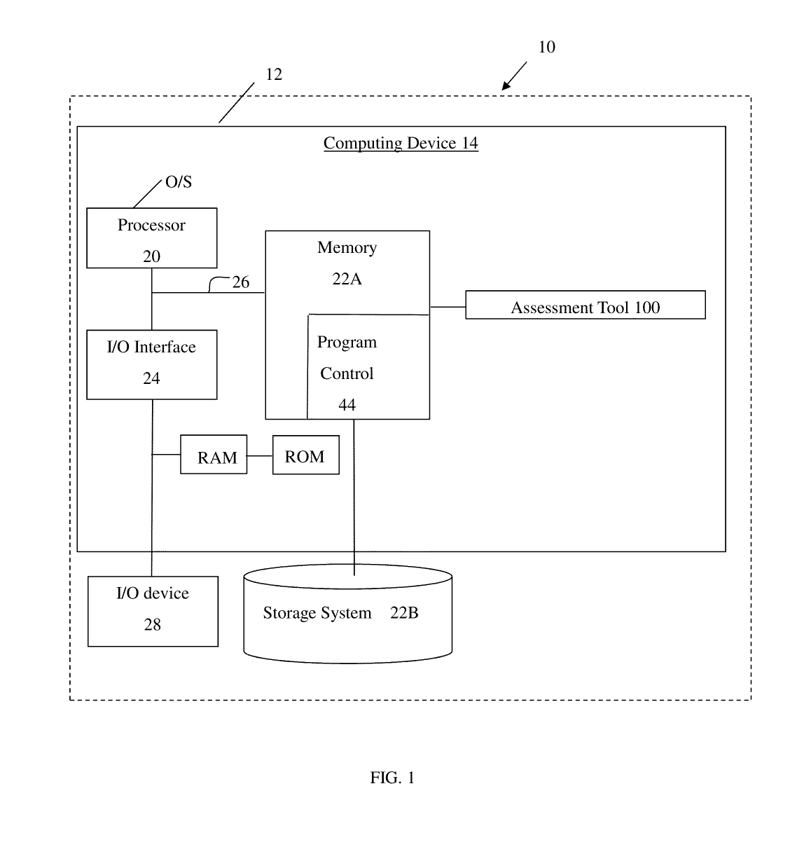

FIG. 1 shows an illustrative environment 10 for managing the processes in accordance with the invention. To this extent, the environment 10 includes a server or other computing system 12 that can perform the processes described herein. In particular, the server 12 includes a computing device 14. The computing device 14 can be resident on a network infrastructure or computing device of a third party service provider (any of which is generally represented in FIG. 1).

The computing device 14 also includes a processor 20, memory 22A, an I/O interface 24, and a bus 26. The memory 22A can include local memory employed during actual execution of program code, bulk storage, and cache memories which provide temporary storage of at least some program code in order to reduce the number of times code must be retrieved from bulk storage during execution. In addition, the computing device includes random access memory (RAM), a read-only memory (ROM), and an operating system (O/S).

The computing device 14 is in communication with the external I/O device/resource 28 and the storage system 22B. For example, the I/O device 28 can comprise any device that enables an individual to interact with the computing device 14 (e.g., user interface) or any device that enables the computing device 14 to communicate with one or more other computing devices using any type of communications link. The external I/O device/resource 28 may be for example, a handheld device, PDA, handset, keyboard, etc.

In general, the processor 20 executes computer program code (e.g., program control 44), which can be stored in the memory 22A and/or storage system 22B. Moreover, in accordance with aspects of the invention, the program control 44 controls an assessment tool 100 to perform the processes described herein. The assessment tool 100 can be implemented as one or more program code in the program control 44 stored in memory 22A as separate or combined modules. Additionally, the assessment tool 100 (e.g., an electronic design automation (EDA) tool) may be implemented as separate dedicated processors or a single or several processors to provide the function of this tool. While executing the computer program code, the processor 20 can read and/or write data to/from memory 22A, storage system 22B, and/or I/O interface 24. The program code executes the processes of the invention. The bus 26 provides a communications link between each of the components in the computing device 14.

In embodiments, the assessment tool 100 may be configured to obtain scan data of a laminate and at least one chip, and thereafter, customize C4 bump and laminate pre-solder characteristics based on the data. For example, in accordance with aspects of the present invention, the assessment tool 100 may be configured to obtain scan data of a laminate and at least one chip, record C4 bump and laminate pre-solder characteristics, input the C4 bump and laminate pre-solder characteristics into a database and/or flow, customize the C4 bump and laminate pre-solder characteristics based on the data, and attach and reflow the laminate and the at least one chip.

The computing device 14 can comprise any general purpose computing article of manufacture capable of executing computer program code installed thereon (e.g., a personal computer, server, etc.). However, it is understood that computing device 14 is only representative of various possible equivalent-computing devices that may perform the processes described herein. To this extent, in embodiments, the functionality provided by computing device 14 can be implemented by a computing article of manufacture that includes any combination of general and/or specific purpose hardware and/or computer program code. In each embodiment, the program code and hardware can be created using standard programming and engineering techniques, respectively.

Similarly, computing infrastructure 12 is only illustrative of various types of computer infrastructures for implementing the invention. For example, in embodiments, server 12 comprises two or more computing devices (e.g., a server cluster) that communicate over any type of communications link, such as a network, a shared memory, or the like, to perform the process described herein. Further, while performing the processes described herein, one or more computing devices on server 12 can communicate with one or more other computing devices external to server 12 using any type of communications link. The communications link can comprise any combination of wired and/or wireless links; any combination of one or more types of networks (e.g., the Internet, a wide area network, a local area network, a virtual private network, etc.); and/or utilize any combination of transmission techniques and protocols.

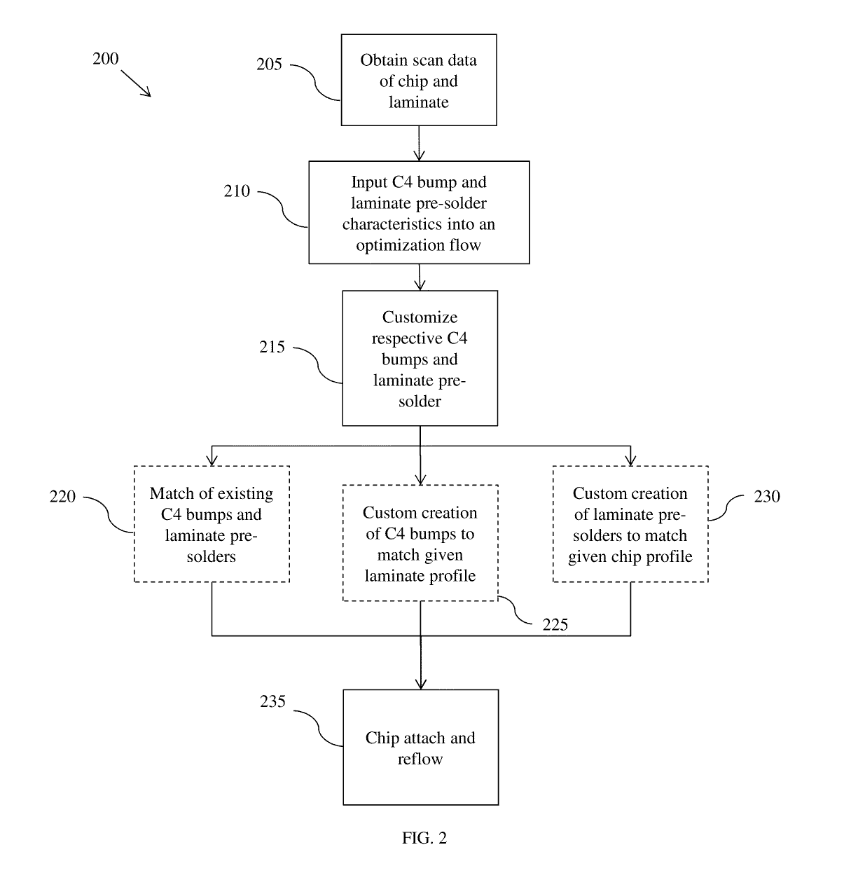

FIGS. 2, 7 and 9 show exemplary flows for performing aspects of the present invention. The steps of FIGS. 2, 7, and 9 may be implemented in the environment of FIG. 1, for example.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

### General Join Optimization

Aspects of the present invention pertain to IC design and fabrication. As should be understood by those of skill in the art, the process for the design and fabrication of an IC may start with the design of a product idea (e.g., a chip design), which may be realized using EDA software such as that described above with respect to FIG. 1. When the design is finalized, it can be taped-out. After tape-out, the fabrication process is consummated and packaging and assembly processes are performed which ultimately result in finished chips.

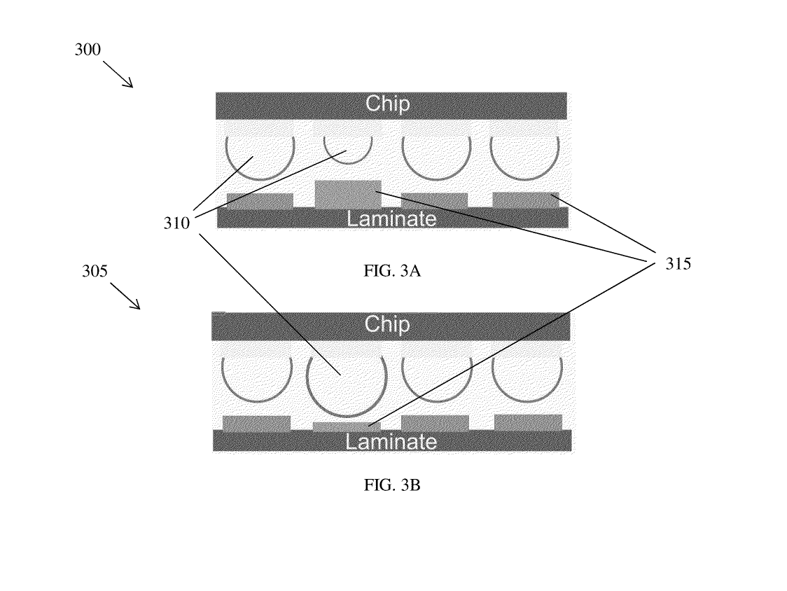

More specifically, FIG. 2 shows a general join optimization design process 200 for at least one semiconductor device. FIGS. 3A, 3B, 4A, 4B, 5, and 6 will be described in conjunction with processes of the general join optimization design process 200 of FIG. 2 in order to better describe the processes and resultant semiconductor device structures.

As shown in FIG. 2, the general join optimization design process 200 may comprise multiple stages that occur during the fabrication process and prior to the assembly process being consummated, which are described below. However, it should be noted that this IC join design optimization description is for illustration purposes only, and is not meant to limit the present invention. For example, an actual IC join design optimization may require a designer and/or manufacturer to perform the IC join design stages in a different sequence than the sequence described herein.

At step 205, scan data may be obtained for at least one semiconductor device (e.g., a 3D chip stack) comprising at least one chip (e.g., an IC chip or circuit board) and a laminate (e.g., a packaging device). In accordance with aspects of the present invention, the scan data may comprise join structure (e.g., C4 bump and laminate pre-solder) characteristics for the at least one chip and laminate. These characteristics may be, for example, volumes and thicknesses of the laminate pre-solder (e.g., a first join structure) and/or the C4 bumps (e.g., a second join structure). In embodiments, the scan data may be existing scan data obtained during fabrication processes of the laminate and the at least one chip. In additional or alternative embodiments, the scan data may be obtained dynamically during assembly processes of the at least one semiconductor device.

For example, the scan data may be obtained from existing wafer inspection systems, such as scan data obtained from a Robotic Vision Systems Inc (RVSI) scanner capable of providing a 2D and/or 3D scan profile comprising the laminate, the at least one chip or circuit board, the C4 bump, and the laminate pre-solder. As illustrated in FIGS. 3A-B, 2D scan profiles 300 and 305 may provide scan data comprising C4 bump and laminate pre-solder characteristics including volumes and/or thicknesses of the C4 bumps 310 and laminate pre-solders 315. The volumes and/or thicknesses of the C4 bumps 310 and laminate pre-solders 315 may be utilized to provide a C4 bump configuration or pre-solder configuration for the at least one chip and the laminate.

At step 210, the C4 bump and laminate pre-solder characteristics may be input into an optimization flow, as described herein. In embodiments, the C4 bump and laminate pre-solder characteristics may be input into a database (e.g., a database on storage system 22B) and the optimization flow. In accordance with aspects of the present invention, the optimization flow may include: (i) comparing the volumes and/or thicknesses of the C4 bumps to respective volumes and/or thicknesses of the laminate pre-solders, (ii) determining whether the volumes and/or thicknesses of the respective C4 bumps and laminate pre-solders match up to avoid contact defects and provide optimal contact, and (iii) if the respective C4 bumps and laminate pre-solders do not match up to avoid the contact defects and provide optimal contact, then determining that customization of the respective C4 bumps and laminate pre-solders may be required to avoid the contact defects and provide optimal contact.

For example, the optimization flow may include comparing the volumes and/or thicknesses of respective C4 bumps 310 and laminate pre-solders 315 (as shown in FIGS. 3A-B), and making a determination as to whether there is a risk that the volumes and/or thicknesses of respective C4 bumps 310 and laminate pre-solders 315 may potentially cause non-wets from a lack of contact (e.g., low volume) between the respective C4 bumps 310 and laminate pre-solders 315. Similarly, the optimization flow may determine whether there may be a risk of the formation of solder bridging or micro solder balls from excess solder (e.g., high volume) between the respective C4 bumps 310 and laminate pre-solder 315. If the respective C4 bumps and laminate pre-solders may potentially cause non-wets, solder bridging, and/or micro solder balls, then the optimization flow may determine that customization of the respective C4 bumps and laminate pre-solders may be required to avoid the risk of non-wets, solder bridging, and/or micro solder balls, and provide optimal contact.

At step 215, customization of the respective C4 bumps and laminate pre-solders may be performed based on the risk of contact defects. In accordance with these aspects of the present invention, the volumes and/or thicknesses of the laminate pre-solders may be used as a determinative factor for the volume and/or thickness of the C4 bumps during customization.

Specifically, the customization may optionally comprise performing step 220 of FIG. 2 Step 220 includes matching existing volumes and/or thicknesses of C4 bumps and laminate solders in such a manner that the risk of contact defects is minimized or substantially eliminated, and optimal contact is provided. For example, the scan data for a number of existing fabricated laminates having various laminate pre-solder configurations may be compared to the scan data for a number of existing fabricated chips having various C4 bump configurations in order to determine which volumes and/or thicknesses of respective laminate pre-solders and C4 bumps reduce the risk of non-wets, solder bridging, and/or micro solder balls from occurring during attachment and reflow.

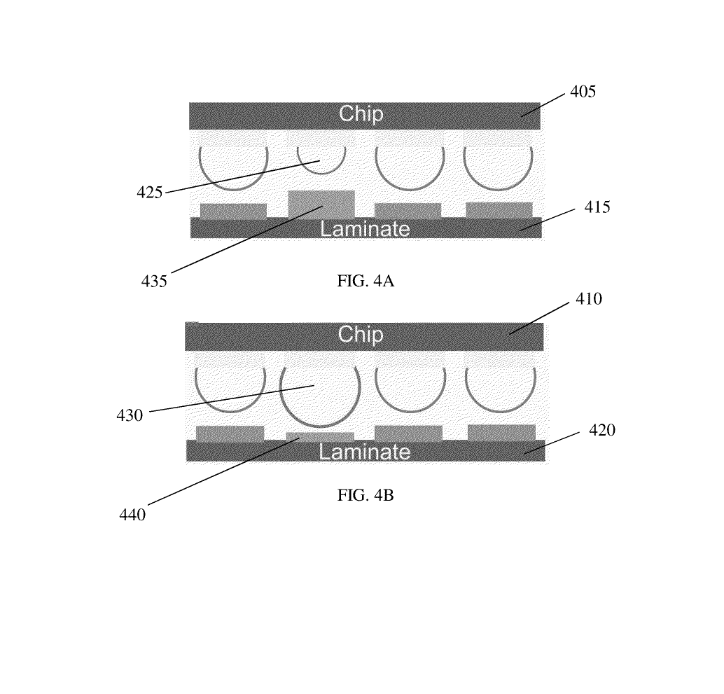

As illustrated in FIGS. 4A-4B, existing fabricated chips 405, 410 may be selected from a plurality of chips to match up respectively with existing fabricated laminates 415, 420 selected from a plurality of laminates. This may occur because the volumes and/or thicknesses of the C4 bumps 425, 430 counteracts respectively the volumes and/or thicknesses of the laminate pre-solders 435, 440 in such a manner that there is a reduction in the risk of non-wets, solder bridging, and/or micro solder balls from occurring during attachment and reflow. For example, the low volume C4 bump 425 matches well with the thicker laminate pre-solder 435 such that there is minimal risk of no contact between the C4 bump 425 and the laminate pre-solder 435, and minimal risk that there is excess solder from the contact of the C4 bump 425 and the laminate pre-solder 435. Additionally, the high volume C4 bump 430 matches well with the thinner laminate pre-solder 440 such that there is minimal risk of no contact between the C4 bump 430 and the laminate pre-solder 440, and minimal risk that there is excess solder from the contact of the C4 bump 430 and the laminate pre-solder 440.

In embodiments, the customization may optionally comprise performing step 225 of FIG. 2. Step 225 includes the custom creation of C4 bumps to match a given laminate or package profile in such a manner that the risk of contact defects is minimized or substantially eliminated, and optimal contact is provided. For example, the existing C4 bumps of the at least one chip may be reworked (e.g., may be removed from the at least one chip and replaced with customized C4 bumps via 3D printing) such that the volumes and/or thicknesses of the customized C4 bumps (e.g., customized solder configuration) match with the respective volumes and/or thicknesses of the given laminate pre-solders (e.g., existing pre-solder configuration) from the at least one existing fabricated laminate. This should reduce the risk of non-wets, solder bridging, and/or micro solder balls from occurring during attachment and reflow.

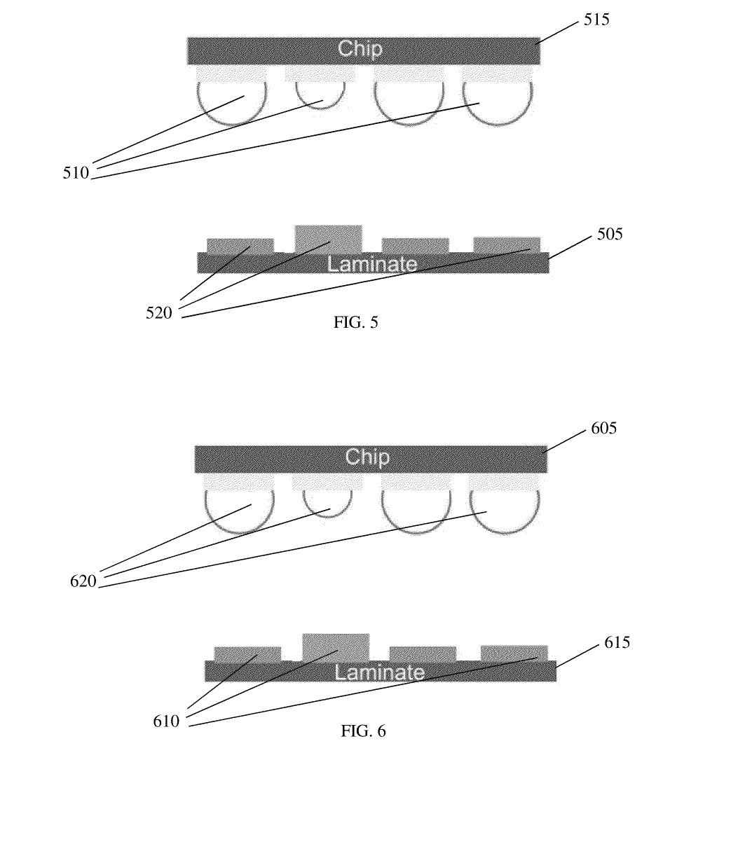

As illustrated in FIG. 5, an existing fabricated laminate 505 may be selected from a plurality of laminates. Existing C4 bumps 510 of chip 515 may thereafter be reworked in view of the scan data for the existing fabricated laminate 505. In this rework, the volume and/or thicknesses of the C4 bumps 510 may be customized to match up or counteract the volumes and/or thicknesses of the laminate pre-solders 520 in such a manner that there is a reduction in the risk of non-wets, solder bridging, and/or micro solder balls from occurring during attachment and reflow.

In embodiments, the customization may optionally comprise performing step 230 of FIG. 2. Step 230 includes the custom creation of laminate pre-solders to match a given chip profile in such a manner that the risk of contact defects is minimized or substantially eliminated, and optimal contact is provided. For example, the existing laminate pre-solders of the at least one laminate may be reworked (e.g., removed from the at least one laminate and replaced with customized laminate pre-solders via 3D printing) such that the volumes and/or thicknesses of the customized laminate pre-solders (e.g., customized pre-solder configuration) match with the respective volumes and/or thicknesses of the given C4 bumps (e.g., existing solder configuration) from the at least one existing fabricated chip. This should reduce the risk of non-wets, solder bridging, and/or micro solder balls from occurring during attachment and reflow.

As illustrated in FIG. 6, an existing fabricated chip 605 may be selected from a plurality of chips. Existing laminate pre-solder 610 of laminate 615 may thereafter be reworked in view of the scan data for the existing fabricated 605 such that the volume and/or thicknesses of the laminate pre-solder 610 match up or counteract the volumes and/or thicknesses of the C4 bumps 620. In this way, there is a reduction in the risk of non-wets, solder bridging, and/or micro solder balls from occurring during attachment and reflow.

At step 235 of FIG. 2, the selected and/or custom fabricated chip and the selected and/or custom fabricated laminate may be attached and reflowed. In embodiments, the attachment and reflow process may comprise using a solder paste (a sticky mixture of powdered solder and flux) to temporarily attach the selected and/or custom fabricated chip and the selected and/or custom fabricated laminate, after which the entire assembly is subjected to controlled heat, which melts the solder, permanently connecting the joint. Heating may be accomplished by passing the assembly through a reflow oven or under an infrared lamp or by soldering individual joints with a hot air pencil.

Accordingly, embodiments of the present invention provide improved prevention of contact defects (e.g., non-wets, soldering bridging, and the formation of micro solder balls), and provide for optimal contact and structural integrity of the joined substrates.

### Chip to Laminate Join Optimization

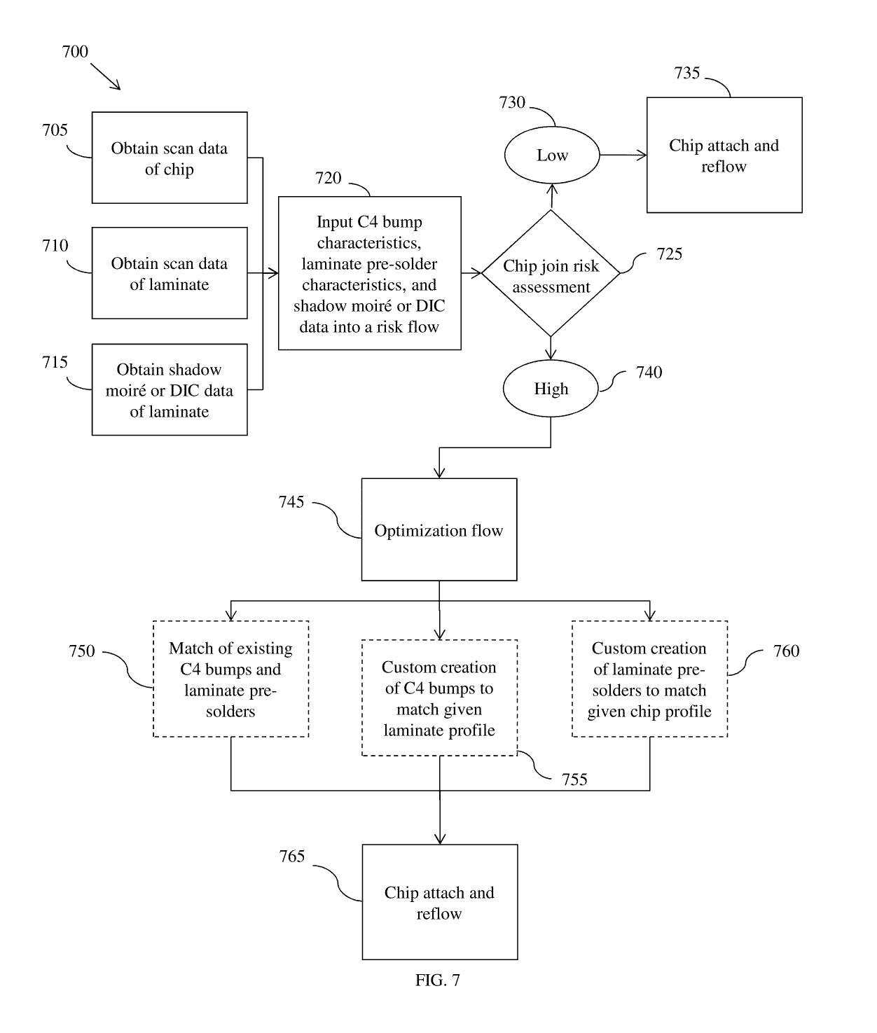

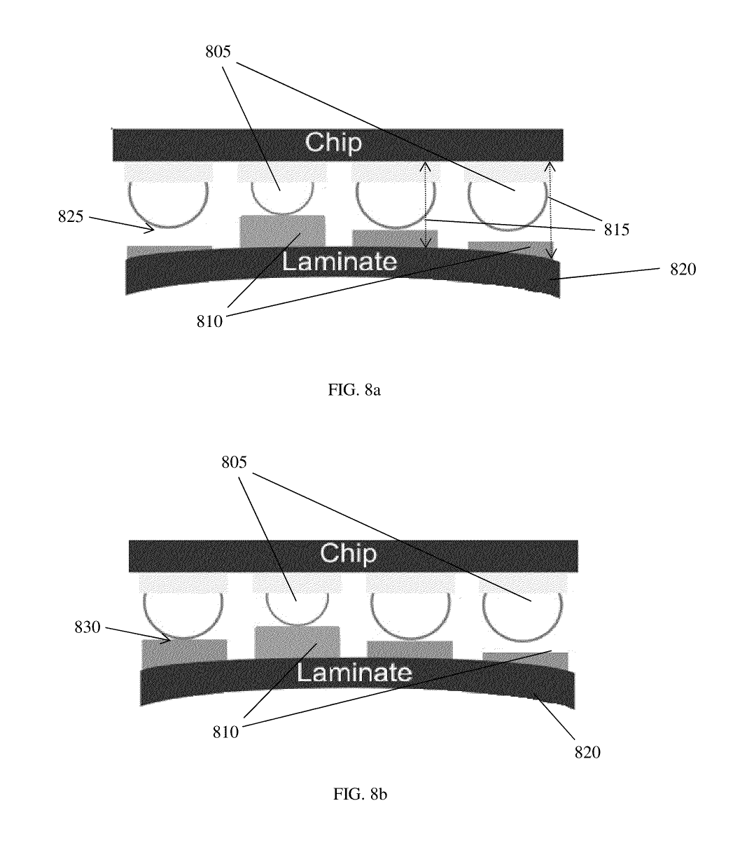

FIG. 7 shows a chip to laminate join optimization design process 700 for at least one semiconductor device. FIGS. 8A and 8B will be described in conjunction with processes of the chip to laminate join optimization design process 700 of FIG. 7 in order to better describe the processes and resultant semiconductor device structures.

As shown in FIG. 7, the chip to laminate join optimization design process 700 may comprise multiple stages that occur during the semiconductor fabrication process and prior to the semiconductor process being consummated. However, it should be noted that this IC join design optimization description is for illustration purposes only, and is not meant to limit the present invention. For example, an actual IC join design optimization may require a designer and/or manufacturer to perform the IC join design stages in a different sequence than the sequence described herein.

At step 705, scan data may be obtained for at least one chip, or at least one semiconductor device (e.g., a 3D chip stack) comprising the at least one chip. In accordance with aspects of the present invention, the scan data may comprise join structure (e.g., C4 bump) characteristics for the at least one chip. In embodiments, the scan data may be existing scan data obtained during fabrication processes of the at least one chip. In additional or alternative embodiments, the scan data may be obtained dynamically during assembly processes of the at least one semiconductor device.

At step 710, scan data may be obtained for at least one laminate, or the at least one semiconductor device comprising the at least one laminate. In accordance with aspects of the present invention, the scan data may comprise join structure (e.g., laminate pre-solder) characteristics for the at least one laminate. In embodiments, the scan data may be existing scan data obtained during fabrication processes of the laminate. In additional or alternative embodiments, the scan data may be obtained dynamically during assembly processes of the at least one semiconductor device.

At step 715, shadow moiré or differential interference contrast (DIC) data may be obtained for the at least one laminate, or the at least one semiconductor device comprising the at least one laminate. In accordance with aspects of the present invention, the shadow moiré or DIC data may comprise laminate profile measurements to calculate warpage of the at least one laminate. For example, shadow moiré is a well-known technique for defect inspection and profile measurements covering a wide range of resolution. In embodiments, the shadow moiré or DIC data may be existing data obtained during fabrication processes of the laminate. In additional or alternative embodiments, the shadow moiré or DIC data may be obtained dynamically during assembly processes of the at least one semiconductor device.

At step 720, the C4 bump characteristics, laminate pre-solder characteristics, and the shadow moiré or DIC data may be input into a risk flow. In embodiments, the C4 bump characteristics, laminate pre-solder characteristics, and the shadow moiré or DIC data may be recorded or input into a database (e.g., a database on storage system 22B), and the risk flow.

At step 725, a chip to laminate join defect risk assessment may be performed using the risk flow. In accordance with aspects of the present invention, the risk flow may include determining whether there is a chip to laminate join reliability risk or connectability issue. For example, the risk flow may include: (i) collecting a plurality of chip to laminate join profile data with known failures, (ii) comparing the input C4 bump characteristics, laminate pre-solder characteristics, and the shadow moiré or DIC data to the plurality of the chip to laminate join profile data, and (iii) making a statistical determination as to whether there is a risk that the volumes and/or thicknesses of respective C4 bumps and laminate pre-solders, and the shadow moiré or DIC data (e.g., warpage data) may potentially cause defects or connectibility issues within the fabricated at least one semiconductor device. In embodiments, the plurality of chip to laminate join profile data may be stored in a database (e.g., a database on storage system 22B).

As illustrated in FIG. 8A, the statistical determination made in the risk flow may include determining whether there is a risk that the volumes and/or thicknesses of respective C4 bumps 805 and laminate pre-solders 810 may potentially cause non-wets from a lack of contact (e.g., low volume) between the respective C4 bumps 805 and laminate pre-solders 810, or the formation of solder bridging or micro solder balls from excess solder (e.g., high volume) between the respective C4 bumps 805 and laminate pre-solders 810. Additionally, the statistical determination made in the risk flow may include determining warpage 815 between the various substrates (e.g., laminate and chip) using the shadow moiré or DIC data 820 and whether there is a risk that the warpage 815 may potentially cause a lack of contact or non-wets 825 between respective C4 bumps 805 and laminate pre-solders 810, or the formation of solder bridging or micro solder balls from excess compression between the respective C4 bumps 805 and laminate pre-solders 810.

At step 730, if there is determination from implementation of the risk flow that there may be a low join reliability risk or connectability issue between respective C4 bumps and laminate pre-solders, then the process may continue at step 735. In embodiments, the determination of a low join reliability risk or connectability issue may be based on comparison of the statistical data calculated in the risk flow to preselected thresholds for risk assessment.

At step 735, the at least one chip and the laminate may be attached and reflowed. In embodiments, the attachment and reflow process may comprise using a solder paste (a sticky mixture of powdered solder and flux) to temporarily attach the at least one chip and the laminate. Thereafter, the entire assembly may be subjected to controlled heat, which melts the solder, and permanently connects the joint. Heating may be accomplished by passing the assembly through a reflow oven or under an infrared lamp or by soldering individual joints with a hot air pencil.

At step 740, if there is determination from implementation of the risk flow that there may be a high join reliability risk or connectability issue between respective C4 bumps and laminate pre-solders, then the flow determines that customization of the respective C4 bumps and laminate pre-solders may be required to avoid the join reliability risk or connectability issue. In embodiments, the determination of a high join reliability risk or connectability issue may be based on comparison of the statistical data calculated in the risk flow to preselected thresholds for risk assessment.

At step 745, the C4 bump characteristics, laminate pre-solder characteristics, and the shadow moiré or DIC data may be input into an optimization flow. In accordance with aspects of the present invention, the optimization flow may include: (i) comparing volumes and/or thicknesses of the C4 bumps to respective volumes and/or thicknesses of laminate pre-solders in view of the shadow moiré or DIC data for the laminate, (ii) determining whether the volumes and/or thicknesses of respective C4 bumps and laminate pre-solders match up to avoid contact defects and provide optimal contact in view of the warpage of the laminate, and (iii) if the respective C4 bumps and laminate pre-solders do not match up to avoid the contact defects and provide optimal contact in view of the warpage of the laminate, then determining that customization of the respective C4 bumps and laminate pre-solders may be required to avoid the contact defects and provide optimal contact.

For example, as illustrated in FIGS. 8A and 8B, the optimization flow may include: (i) comparing volumes and/or thicknesses of the C4 bumps 805 to respective volumes and/or thicknesses of laminate pre-solders 810 in view of the shadow moiré or DIC data 820 for the laminate, (ii) determining whether the volumes and/or thicknesses of respective C4 bumps and laminate pre-solders match up to avoid contact defects and provide optimal contact in view of the warpage 815 of the laminate (as can be seen the volumes and/or thicknesses of respective C4 bumps 805 and laminate pre-solders 810 do not match up at non-wet 825 in view of the warpage 815 to the laminate), and (iii) if the respective C4 bumps 805 and laminate pre-solders 810 do not match up to avoid the contact defects and provide optimal contact in view of the warpage of the laminate, then determining that customization of the respective C4 bumps 805 and laminate pre-solders 810 may be required to avoid the contact defects and provide optimal contact (as can be seen the laminate pre-solders 810 configuration can be dynamically built up or enlarged 830 (e.g., customized) to offset the effect of the warpage 815 (i.e., reduce a gap between the substrates)).

The customization of the respective C4 bumps and laminate pre-solders may optionally comprise performing step 750. Step 750 includes matching existing volumes and/or thicknesses of C4 bumps with the given laminate pre-solders and warpage profiles of the laminate in such a manner that the risk of contact defects is minimized or substantially eliminated, and optimal contact is provided. For example, the scan data for a number of existing fabricated chips having C4 bumps may be compared to the scan data for the laminate pre-solders and the shadow moiré or DIC data of the laminate in order to determine which volumes and/or thicknesses of respective laminate pre-solders and C4 bumps reduce the risk of non-wets, solder bridging, and/or micro solder balls from occurring during attachment and reflow. In embodiments, the scan data comprising existing volumes and/or thicknesses of C4 bumps may be obtained from the database (e.g., the database on the storage system 22B).

In embodiments, the customization may optionally comprise performing step 755. Step 755 includes the custom creation of C4 bumps to match a given laminate or package profile in such a manner that the risk of contact defects is minimized or substantially eliminated, and optimal contact is provided. For example, the existing C4 bumps of the at least one chip may be reworked (e.g., removed from the at least one chip and replaced with customized C4 bumps via 3D printing). In this way, the volumes and/or thicknesses of the customized C4 bumps match with the respective volumes and/or thicknesses of the given laminate pre-solder and the warpage profile from the at least one existing fabricated laminate. This should reduce the risk of non-wets, solder bridging, and/or micro solder balls from occurring during attachment and reflow.

In embodiments, the customization may optionally comprise performing step 760. Step 760 includes the custom creation of laminate pre-solders in view of the warpage profile for the at least one laminate to match a given chip profile in such a manner that the risk of contact defects is minimized or substantially eliminated, and optimal contact is provided. For example, the existing laminate pre-solders of the at least one laminate may be reworked (e.g., removed from the at least one laminate and replaced with customized laminate pre-solders via 3D printing). In this way, the volumes and/or thicknesses of the customized laminate pre-solders in view of the warpage profile for the at least one laminate match with the respective volumes and/or thicknesses of the given C4 bumps from the at least one existing fabricated chip. This should reduce the risk of non-wets, solder bridging, and/or micro solder balls from occurring during attachment and reflow.

At step 765, the selected and/or custom fabricated chip and the selected and/or custom fabricated laminate may be attached and reflowed. In embodiments, the attachment and reflow process may comprise using a solder paste (a sticky mixture of powdered solder and flux) to temporarily attach the selected and/or custom fabricated chip and the selected and/or custom fabricated laminate, after which the entire assembly is subjected to controlled heat, which melts the solder, permanently connecting the joint. Heating may be accomplished by passing the assembly through a reflow oven or under an infrared lamp or by soldering individual joints with a hot air pencil.

Accordingly, embodiments of the present invention provide improved prevention of contact defects (e.g., non-wets, soldering bridging, and the formation of micro solder balls), and provide for optimal contact and structural integrity of the joined substrates. Additionally, the dynamic matching of the size of the individual C4 bumps to the laminate pre-solder for the adjoining chip and laminate may be utilized to compensate for the laminate warpage.

### Chip to Chip Join Optimization

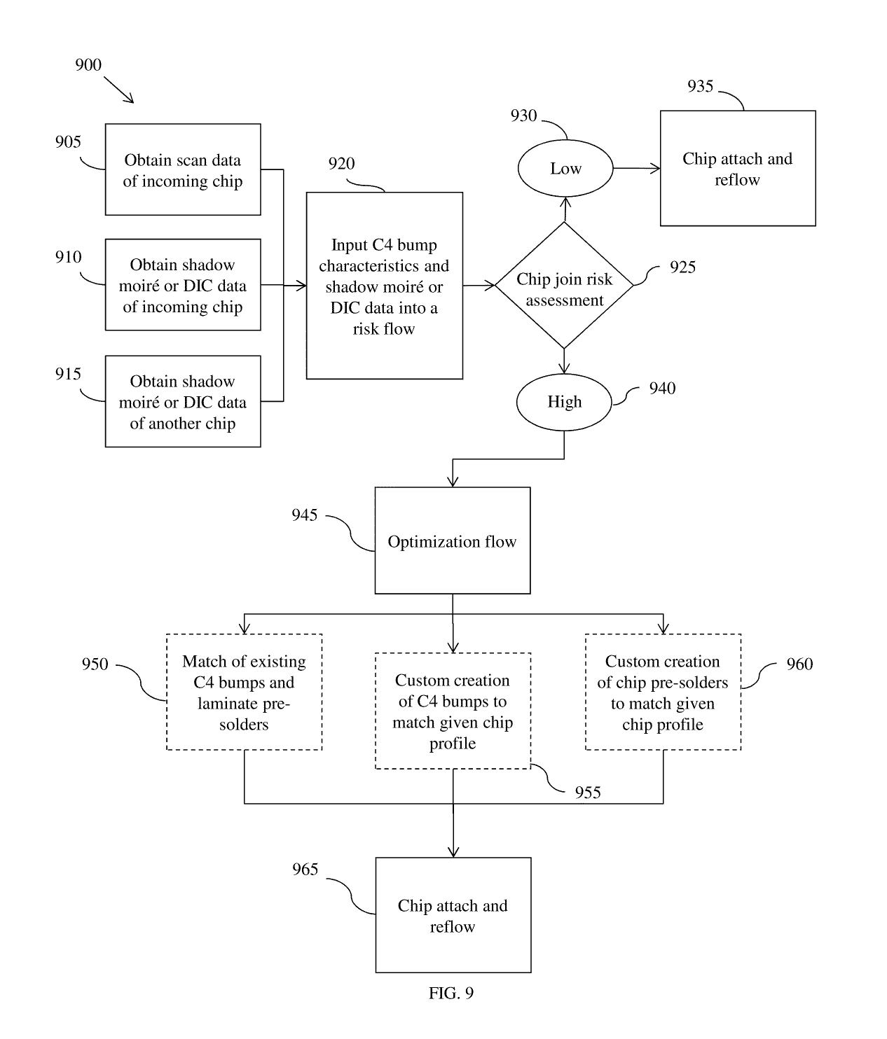

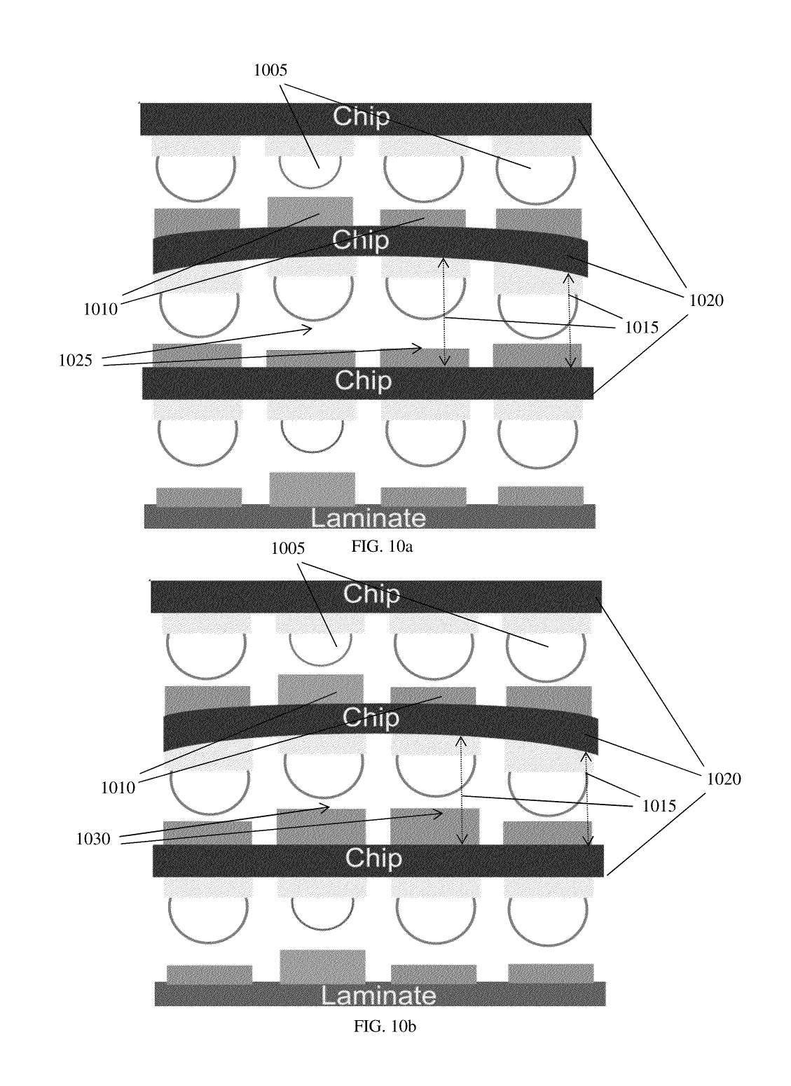

FIG. 9 shows a chip to chip join optimization design process 900 for at least one semiconductor device. FIGS. 10A and 10B will be described in conjunction with processes of the chip to chip join optimization design process 900 of FIG. 9 in order to better describe the processes and resultant semiconductor device structures.

As shown in FIG. 9, the chip to chip join optimization design process 900 may comprise multiple stages that occur during the semiconductor fabrication process and prior to the semiconductor assembly process being consummated, which are described below. However, it should be noted that this IC join design optimization description is for illustration purposes only. This description is not meant to limit the present invention. For example, an actual IC join design optimization may require a designer and/or manufacturer to perform the IC join design stages in a different sequence than the sequence described herein.

At step 905, scan data may be obtained for at least one incoming chip, or at least one semiconductor device (e.g., a 3D chip stack) comprising the at least one incoming chip. In accordance with aspects of the present invention, the scan data may comprise join structure (e.g., C4 bump) characteristics for the at least one incoming chip. The incoming chip may be any chip that is being attached to another chip to construct a chip stack. In embodiments, the scan data may be existing scan data obtained during fabrication processes of the at least one chip. In additional or alternative embodiments, the scan data may be obtained dynamically during assembly processes of the at least one semiconductor device.

At step 910, shadow moiré or DIC data may be obtained for the at least one incoming chip, or the at least one semiconductor device comprising the at least one incoming chip. In accordance with aspects of the present invention, the shadow moiré or DIC data may comprise chip profile measurements to calculate warpage of the at least one incoming chip. In embodiments, the shadow moiré or DIC data may be existing data obtained during fabrication processes of the incoming chip. In additional or alternative embodiments, the shadow moiré or DIC data may be obtained dynamically during assembly processes of the at least one semiconductor device.

At step 915, shadow moiré or DIC data may be obtained for the another chip that may be attached to the incoming chip, or the at least one semiconductor device comprising the another chip. In accordance with aspects of the present invention, the shadow moiré or DIC data may comprise chip profile measurements to calculate warpage of the another chip and/or the chip stack. In embodiments, the shadow moiré or DIC data may be existing data obtained during fabrication processes of the another chip. In additional or alternative embodiments, the shadow moiré or DIC data may be obtained dynamically during assembly processes of the at least one semiconductor device or chip stack.

At step 920, the C4 bump characteristics of the incoming chip, the shadow moiré or DIC data of the incoming chip, chip pre-solder (e.g., the pads) characteristics of the another chip, and the shadow moiré or DIC data of the another chip may be input into a risk flow. In embodiments, the chip pre-solder characteristics of the incoming chip should already be recorded within the database from previous chip join optimization processes such as when the another chip was joined to the laminate or another chip of the chip stack. In embodiments, the C4 bump characteristics of the incoming chip, the shadow moiré or DIC data of the incoming chip, and the shadow moiré or DIC data of the another chip may be recorded or input into the database (e.g., the database on storage system 22B), and the risk flow.

At step 925, a chip to chip join defect risk assessment may be performed using the risk flow. In accordance with aspects of the present invention, the risk flow may include determining whether there is a chip to chip join reliability risk or connectability issue. For example, the risk flow may include: (i) collecting a plurality of chip to chip join profile data with known failures, (ii) comparing the input C4 bump characteristics of the incoming chip, the shadow moiré or DIC data of the incoming chip, the chip pre-solder characteristics of the another chip, and the shadow moiré or DIC data of the another chip to the plurality of the chip to chip join profile data, and (iii) making a statistical determination as to whether there is a risk that the volumes and/or thicknesses of respective C4 bumps and chip pre-solders, and the shadow moiré or DIC data (e.g., warpage data) may potentially cause defects or connectibility issues within the fabricated at least one semiconductor device. In embodiments, the plurality of chip to chip join profile data may be stored in the database (e.g., the database on storage system 22B).

As illustrated in FIG. 10A, the statistical determination made in the risk flow may include determining whether there is a risk that the volumes and/or thicknesses of respective C4 bumps 1005 and chip pre-solders 1010 may potentially cause non-wets from a lack of contact (e.g., low volume) between the respective C4 bumps 1005 and chip pre-solders 1010, or the formation of solder bridging or micro solder balls from excess solder (e.g., high volume) between the respective C4 bumps 1005 and chip pre-solder 1010. Additionally, the statistical determination made in the risk flow may include determining warpage 1015 between the various substrates (e.g., chips) using the shadow moiré or DIC data 1020 and whether there is a risk that the warpage 1015 may potentially cause a lack of contact or non-wets 1025 between respective C4 bumps 1005 and chip pre-solders 1010, or the formation of solder bridging or micro solder balls from excess compression between the respective C4 bumps 1005 and chip pre-solders 1010.

At step 930, if there is determination from implementation of the risk flow that there may be a low join reliability risk or connectability issue between respective C4 bumps and chip pre-solders, then the process may continue at step 935. In embodiments, the determination of a low join reliability risk or connectability issue may be based on comparison of the statistical data calculated in the risk flow to preselected thresholds for risk assessment. At step 935, the chip and the another chip may be attached and reflowed, as discussed herein.

At step 940, if there is determination from implementation of the risk flow that there may be a high join reliability risk or connectability issue between respective C4 bumps and chip pre-solders, then the risk flow determines that customization of the respective C4 bumps and chip pre-solders may be required to avoid the join reliability risk or connectability issue. In embodiments, the determination of a high join reliability risk or connectability issue may be based on comparison of the statistical data calculated in the risk flow to preselected thresholds for risk assessment.

At step 945, the C4 bump characteristics of the incoming chip, the shadow moiré or DIC data of the incoming chip, chip pre-solder characteristics of the another chip, and the shadow moiré or DIC data of the another chip may be input into an optimization flow. In accordance with aspects of the present invention, the optimization flow may include: (i) comparing volumes and/or thicknesses of the C4 bumps to respective volumes and/or thicknesses of chip pre-solders in view of the shadow moiré or DIC data for the chips, (ii) determining whether the volumes and/or thicknesses of respective C4 bumps and chip pre-solders match up to avoid contact defects and provide optimal contact in view of the warpage of the incoming chip and/or the another chip, and (iii) if the respective C4 bumps and chip pre-solders do not match up to avoid the contact defects and provide optimal contact in view of the warpage of the incoming chip and/or the another chip, then determining that customization of the respective C4 bumps and chip pre-solders may be required to avoid the contact defects and provide optimal contact.

For example, as illustrated in FIGS. 10A and 10B, the optimization flow may include: (i) comparing volumes and/or thicknesses of the C4 bumps 1005 to respective volumes and/or thicknesses of chip pre-solders 1010 in view of the shadow moiré or DIC data 1020 for the chips, (ii) determining whether the volumes and/or thicknesses of respective C4 bumps 1005 and chip pre-solders 1010 match up to avoid contact defects and provide optimal contact in view of the warpage 1015 of the incoming chip and/or the another chip (as can be seen the volumes and/or thicknesses of respective C4 bumps 1005 and the chip pre-solders 1010 do not match up at non-wets 1025 in view of the warpage 1015 to the chips), and (iii) if the respective C4 bumps 1005 and chip pre-solders 1010 do not match up to avoid the contact defects and provide optimal contact in view of the warpage of the incoming chip and/or the another chip, then determining that customization of the respective C4 bumps 1005 and chip pre-solders 1010 may be required to avoid the contact defects and provide optimal contact (as can be seen the chip pre-solders 1010 configuration can be dynamically built up or enlarged 1030 (e.g., customized) to offset the effect of the warpage 1015 (i.e., reduce a gap between the substrates)).

The customization of the respective C4 bumps and chip pre-solders may optionally comprise performing step 950. Step 950 includes matching existing volumes and/or thicknesses of C4 bumps with the given chip pre-solders and warpage profiles of the another chip in such a manner that the risk of contact defects is minimized or substantially eliminated, and optimal contact is provided. For example, the scan data for a number of existing fabricated chips having C4 bumps may be compared to the scan data for the chip pre-solders and the shadow moiré or DIC data of the another chip in order to determine which volumes and/or thicknesses of respective chip pre-solders and C4 bumps reduce the risk of non-wets, solder bridging, and/or micro solder balls from occurring during attachment and reflow. In embodiments, the scan data comprising existing volumes and/or thicknesses of C4 bumps may be obtained from the database (e.g., the database on the storage system 22B).

In embodiments, the customization may optionally comprise performing step 955. Step 955 includes the custom creation of C4 bumps to match a given another chip or package profile in such a manner that the risk of contact defects is minimized or substantially eliminated, and optimal contact is provided. For example, the existing C4 bumps of the at least one chip may be reworked (e.g., removed from the at least one chip and replaced with customized C4 bumps via 3D printing). In this way, the volumes and/or thicknesses of the customized C4 bumps match with the respective volumes and/or thicknesses of the given chip pre-solder and the warpage profile from the existing fabricated another chip. This should reduce the risk of non-wets, solder bridging, and/or micro solder balls from occurring during attachment and reflow.

In embodiments, the customization may optionally comprise performing step 960. Step 960 includes the custom creation of chip pre-solders in view of the warpage profiles for the another chip to match a given incoming chip profile in such a manner that the risk of contact defects is minimized or substantially eliminated, and optimal contact is provided. For example, the existing chip pre-solders of the another chip may be reworked (e.g., be removed from the another chip and replaced with customized chip pre-solders via 3D printing). In this way, the volumes and/or thicknesses of the customized chip pre-solders in view of the warpage profile for the another chip match with the respective volumes and/or thicknesses of the given C4 bumps from the at least one existing fabricated incoming chip. This should reduce the risk of non-wets, solder bridging, and/or micro solder balls from occurring during attachment and reflow.

At step 965, the selected and/or custom fabricated incoming chip and the fabricated or customized another chip may be attached and reflowed, as discussed herein.

Accordingly, embodiments of the present invention provide improved prevention of contact defects (e.g., non-wets, soldering bridging, and the formation of micro solder balls), and provide for optimal contact and structural integrity of the joined substrates. Additionally, the dynamic matching of the size of the individual C4 bumps to the chip pre-solder for the adjoining chips may be utilized to compensate for the chip warpage.

### Design Process

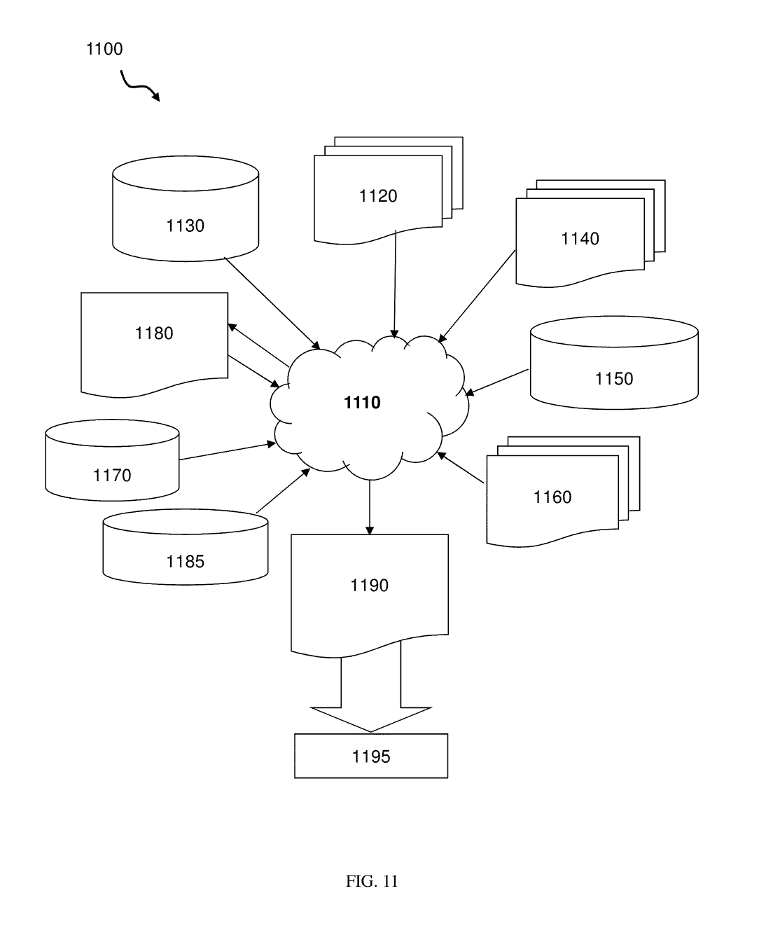

FIG. 11 is a flow diagram of a design process used in semiconductor design, manufacture, and/or test used with the system and method of the present invention. FIG. 11 shows a block diagram of an exemplary design flow 1100 used for example, in semiconductor IC logic design, simulation, test, layout, and manufacture. Design flow 1100 includes processes, machines and/or mechanisms for processing design structures or devices to generate logically or otherwise functionally equivalent representations of the design structures and/or devices. The design structures processed and/or generated by design flow 1100 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 1100 may vary depending on the type of representation being designed. For example, a design flow 1100 for building an application specific IC (ASIC) may differ from a design flow 1100 for designing a standard component or from a design flow 1100 for instantiating the design into a programmable array, for example a programmable gate array (PGA) or a field programmable gate array (FPGA) offered by Altera® Inc. or Xilinx® Inc.

FIG. 11 illustrates multiple such design structures including an input design structure 1120 that is preferably processed by a design process 1110. Design structure 1120 may be a logical simulation design structure generated and processed by design process 1110 to produce a logically equivalent functional representation of a hardware device. Design structure 1120 may also or alternatively comprise data and/or program instructions that when processed by design process 1110, generate a functional representation of the physical structure of a hardware device. Whether representing functional and/or structural design features, design structure 1120 may be generated using electronic computer-aided design (ECAD) such as implemented by a core developer/designer. When encoded on a machine-readable data transmission, gate array, or storage medium, design structure 1120 may be accessed and processed by one or more hardware and/or software modules within design process 1110 to simulate or otherwise functionally represent an electronic component, circuit, electronic or logic module, apparatus, device, or system, which can be implemented with the method and system of the present invention. As such, design structure 1120 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 1110 preferably employs and incorporates hardware and/or software modules for synthesizing, translating, or otherwise processing a design/simulation functional equivalent of the components, circuits, devices, or logic structures to generate a netlist 1180 which may contain design structures such as design structure 1120. Netlist 1180 may comprise, for example, compiled or otherwise processed data structures representing a list of wires, discrete components, logic gates, control circuits, I/O devices, models, etc. that describes the connections to other elements and circuits in an integrated circuit design. Netlist 1180 may be synthesized using an iterative process in which netlist 1180 is resynthesized one or more times depending on design specifications and parameters for the device. As with other design structure types described herein, netlist 1180 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 1110 may include hardware and software modules for processing a variety of input data structure types including netlist 1180. Such data structure types may reside, for example, within library elements 1130 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 1140, characterization data 1150, verification data 1160, design rules 1170, and test data files 1185 which may include input test patterns, output test results, and other testing information. Design process 1110 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 1110 without deviating from the scope and spirit of the invention. Design process 1110 may also include modules for performing standard circuit design processes such as timing analysis, verification, design rule checking, place and route operations, etc.

Design process 1110 employs and incorporates logic and physical design tools such as HDL compilers and simulation model build tools to process design structure 1120 together with some or all of the depicted supporting data structures along with any additional mechanical design or data (if applicable), to generate a second design structure 1190.

Design structure 1190 resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures). Similar to design structure 1120, design structure 1190 preferably comprises one or more files, data structures, or other computer-encoded data or instructions that reside on transmission or data storage media and that when processed by an ECAD system generate a logically or otherwise functionally equivalent form of one or more devices. In one embodiment, design structure 1190 may comprise a compiled, executable HDL simulation model that functionally simulates the devices.

Design structure 1190 may also employ a data format used for the exchange of layout data of integrated circuits and/or symbolic data format (e.g. information stored in a GDSII (GDS2), GL1, OASIS, map files, or any other suitable format for storing such design data structures). Design structure 1190 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure. Design structure 1190 may then proceed to a stage 1195 where, for example, design structure 1190: proceeds to tape-out, is released to manufacturing, is released to a mask house, is sent to another design house, is sent back to the customer, etc.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of manufacturing a semiconductor structure, comprising:
obtaining a characteristic of an existing first join structure on a first substrate and a characteristic of an existing second join structure on a second substrate; and
analyzing the characteristics of the existing first join structure and the existing second join structure to determine a match between the existing first join structure and the existing second join structure to avoid contact defects,
wherein at least the step of the analyzing the characteristics is performed using a processor.

2. The method of claim 1, further comprising when the existing first join structure does not match the existing second join structure, performing one of:
selecting another substrate to match a second join structure or first join structure configuration of the another substrate with a first join structure configuration of the existing first join structure on the first substrate or a second join structure configuration of the existing second join structure on the second substrate;
customizing the existing first join structure on the first substrate; and
customizing the existing second join structure on the second substrate.

3. The method of claim 2, further comprising attaching the first substrate to the second substrate using the existing or customized first join structure on the first substrate and the existing or customized second join structure on the second substrate.

4. The method of claim 2, wherein the characteristic of the existing first join structure comprises a volume or thickness of the existing first join structure on the first substrate and the characteristic of the existing second join structure comprises a volume or thickness of the existing second join structure on the second substrate.

5. The method of claim 4, wherein the customizing the existing first join structure on the first substrate comprises modifying the volume or thickness of the existing first join structure to match the first join structure configuration of the existing first join structure with the second join structure configuration of the existing second join structure.

6. The method of claim 5, wherein the modifying the volume or thickness of the existing first join structure comprises removing the existing first join structure from the first substrate and forming the customized first join structure on the first substrate.

7. The method of claim 4, wherein the customizing the existing second join structure on the second substrate comprises modifying the volume or thickness of the existing second join structure to match the second join structure configuration of the existing second join structure with the first join structure configuration of the existing first join structure.

8. The method of claim 7, wherein the modifying the volume or thickness of the existing second join structure comprises removing the existing second join structure from the second substrate and forming the customized second join structure on the second substrate.

9. The method of claim 1, wherein:
the characteristic of the existing first join structure comprises a volume or thickness of the existing first join structure on the first substrate and the characteristic of the existing second join structure comprises a volume or thickness of the existing second join structure on the second substrate.

10. The method of claim 9, wherein:
the analyzing comprises comparing the volume or thickness of the existing first join structure to the volume or thickness of the existing second join structure to determine whether the volume or thickness of the existing first join structure matches the volume or thickness of the existing second join structure to avoid the contact defects;
when the volume or thickness of the existing first join structure does not match the volume or thickness of the existing second join structure, performing one of: customizing the existing first join structure on the first substrate, and customizing the existing second join structure on the second substrate;
the customizing the existing first join structure on the first substrate comprises modifying the volume or thickness of the existing first join structure to match a first join structure configuration of the existing first join structure with a second join structure configuration of the existing second join structure; and
the customizing the existing second join structure on the second substrate comprises modifying the volume or thickness of the existing second join structure to match a second join structure configuration of the existing second join structure with a first join structure configuration of the existing first join structure.

11. A method of manufacturing a semiconductor structure, comprising:
obtaining scan data of existing pre-solder on a laminate or chip and scan data of existing solder on a chip;
analyzing the scan data of the existing pre-solder and the existing solder to determine whether a match exists between the existing pre-solder and the existing solder to avoid contact defects between the laminate or chip and the chip when attached; and
when the existing pre-solder does not match the existing solder, performing one of:
selecting another substrate to match a solder or pre-solder configuration of the another substrate with a pre-solder configuration of the existing pre-solder on the laminate or chip or a solder configuration of the existing solder on the chip;
customizing the existing pre-solder on the laminate or chip; and
customizing the existing solder on the chip,
wherein at least the step of the analyzing the scan data is performed using a processor.

12. The method of claim 11, further comprising obtaining shadow moiré or differential interference contrast (DIC) data of the laminate or chip; and
wherein:
the scan data of the existing pre-solder comprises a volume or thickness of the existing pre-solder on the laminate or chip; and
the scan data of the existing solder comprises a volume or thickness of the existing solder on the chip.

13. The method of claim 12, wherein:
the analyzing comprises:
comparing the volume or thickness of the existing pre-solder to the volume or thickness of the existing solder in view of the shadow moiré or DIC data of the laminate or chip; and
determining whether the volume or thickness of the existing pre-solder matches the volume or thickness of the existing solder to avoid the contact defects; and
when the volume or thickness of the existing pre-solder does not match the volume or thickness of the existing solder, then performing the selecting of the another substrate, the customizing the existing pre-solder, or the customizing the existing solder.

14. The method of claim 11, further comprising obtaining shadow moiré or DIC data of the laminate or chip and shadow moiré or DIC data of the chip; and
wherein:
the scan data of the laminate or chip comprises a volume or thickness of the existing pre-solder on the laminate or chip; and
the scan data of the chip comprises a volume or thickness of the existing solder on the chip.

15. The method of claim 14, wherein:
the analyzing comprises:
comparing the volume or thickness of the existing pre-solder on the laminate or chip to the volume or thickness of the existing solder on the chip in view of the first shadow moiré or DIC data of the laminate or chip and the second shadow moiré or DIC data of the chip;
determining whether the volume or thickness of the existing pre-solder match the volume or thickness of the existing solder to avoid the contact defects; and
when the volume or thickness of the existing pre-solder does not match the volume or thickness of the existing solder, then performing the selecting of the another substrate, the customizing the existing pre-solder, or the customizing the existing solder.

16. The method of claim 11, further comprising attaching the chip or laminate to the chip using the existing or customized pre-solder on the laminate or chip and the existing or customized solder on the chip.

17. A computer program product comprising a computer readable storage medium having readable program code embodied in the storage medium, the computer program product includes at least one component operable to:
obtain a characteristic of an existing first join structure on a first substrate and a characteristic of an existing second join structure on a second substrate; and
analyze the characteristics of the existing first join structure and the existing second join structure to determine a match between the existing first join structure and the existing second join structure to avoid contact defects.

18. The computer program product of claim 17, wherein when the existing first join structure does not match the existing second join structure, perform one of:
select another substrate to match a second join structure or first join structure configuration of the another substrate with a first join structure configuration of the existing first join structure on the first substrate or a second join structure configuration of the existing second join structure on the second substrate;
customize the existing first join structure on the first substrate; and
customize the existing second join structure on the second substrate.

19. The computer program product of claim 18, wherein the characteristic of the existing first join structure comprises a volume or thickness of the existing first join structure on the first substrate and the characteristic of the existing second join structure comprises a volume or thickness of the existing second join structure on the second substrate.

20. The computer program product of claim 19, wherein:
the customizing the existing first join structure on the first substrate comprises modifying the volume or thickness of the existing first join structure to match the first join structure configuration of the existing first join structure with the second join structure configuration of the existing second join structure; and
the customizing the existing second join structure on the second substrate comprises modifying the volume or thickness of the existing second join structure to match the second join structure configuration of the existing second join structure with the first join structure configuration of the existing first join structure.
